(19) United States
(12) Patent Application Publication
(10) Pub. No.: US 2026/0032812 A1
(43) Pub. Date: Jan. 29, 2026

(54) MULTILAYER CIRCUIT BOARD

(71) Applicant: Murata Manufacturing Co., Ltd., Nagaokakyo-shi (JP)

(72) Inventors: Tomohiro FURUMURA, Nagaokakyo-shi (JP); Yukiya HIRAOKA, Nagaokakyo-shi (JP); Hajime KAYASHIMA, Nagaokakyo-shi (JP); Naoki MINAMIDANI, Nagaokakyo-shi (JP); Suguru OKUMURA, Nagaokakyo-shi (JP)

(21) Appl. No.: 19/343,278

(22) Filed: Sep. 29, 2025

Related U.S. Application Data
(63) Continuation of application No. PCT/JP2024/014334, filed on Apr. 9, 2024.

(30) Foreign Application Priority Data
Apr. 20, 2023 (JP) 2023-069295

(51) Int. Cl. H05K 1/02; H05K 1/09

(52) U.S. Cl. CPC H05K 1/0298; H05K 1/09; H05K 2201/09827

(57) ABSTRACT

A multilayer circuit board includes an insulating base including insulating layers, and first and second main surfaces facing each other in a stacking direction, conductor layers between the insulating layers, or on the first main surface, or on the second main surface, interlayer connection conductors penetrating at least one of the insulating layers, a mounting electrode on the first main surface, and a radiation electrode located closer to the second main surface than the mounting electrode. The conductor layers include first, second, third, and fourth conductor layers each including Cu foil. The interlayer connection conductors include one or more first interlayer connection conductors sandwiched between the first and second conductor layers in the stacking direction, and one or more second interlayer connection conductors sandwiched between the third and fourth conductor layers. in the stacking direction.

### CROSS REFERENCE TO RELATED APPLICATIONS

This application claims the benefit of priority to Japanese Patent Application No. 2023-069295 filed on Apr. 20, 2023 and is a Continuation Application of PCT Application No. PCT/JP2024/014334 filed on Apr. 9, 2024. The entire contents of each application are hereby incorporated herein by reference.

### BACKGROUND OF THE INVENTION

### 1. Field of the Invention

The present invention relates to multilayer circuit boards.

### 2. Description of the Related Art

WO 2021/060168 A discloses an antenna substrate including a dielectric base including a first main surface and a second main surface, and an antenna conductor on the first main surface. WO 2021/060168 A also discloses that a connection conductor is disposed on the second main surface of the dielectric base, and that a circuit substrate and the antenna substrate are connected by a connector mounted on the circuit substrate and the connection conductor mounted on the antenna substrate.

In a multilayer circuit board such as the antenna substrate disclosed in WO 2021/060168 A, it is preferable to shorten the path of the current by directly lowering the interlayer connection conductors from electronic components such as integrated circuits (ICs) to the multilayer circuit board. As a result, the insertion loss can be reduced. Therefore, the interlayer connection conductors connected to the connection conductors (hereinafter, also referred to as mounting electrodes) for the electronic components are desired to be made smaller in diameter and arranged at a narrower pitch.

WO 2021/060168 A discloses a method of forming interlayer connection conductors by filling a hole in a dielectric layer with a conductive paste and solidifying the paste. With this method, however, as the diameter of the hole decreases, the conductive paste is less likely to fill the hole in the depth direction, so that there is a possibility that connection reliability between the interlayer connection conductors and the conductor layers cannot be sufficiently obtained.

### SUMMARY OF THE INVENTION

Example embodiments of the present invention provide multilayer circuit boards that each have excellent connection reliability between interlayer connection conductors and conductor layers, even when the interlayer connection conductors have a small diameter and are arranged at a narrow pitch on a mounting surface for electronic components.

A multilayer circuit board according to an example embodiment of the present invention includes an insulating base including a stack of a plurality of insulating layers, and a first main surface and a second main surface facing each other in a stacking direction, a plurality of conductor layers between the plurality of insulating layers, or on the first main surface, or on the second main surface, a plurality of interlayer connection conductors penetrating at least one of the plurality of insulating layers in the stacking direction, a mounting electrode on the first main surface, and a radiation electrode located closer to the second main surface than the mounting electrode is in the stacking direction. The plurality of conductor layers include a first conductor layer, a second conductor layer, a third conductor layer, and a fourth conductor layer, each including Cu foil. The plurality of interlayer connection conductors include one or more first interlayer connection conductors sandwiched between the first conductor layer and the second conductor layer in the stacking direction, and one or more second interlayer connection conductors sandwiched between the third conductor layer and the fourth conductor layer in the stacking direction. Each of the one or more first interlayer connection conductors includes a first portion and a second portion in the stacking direction, the first portion including a single metal including Cu as a main component, the second portion including an alloy material including two or more metals or a composite material including one or more metals and a resin. One end portion of the first portion is bonded to the first conductor layer, and an other end portion of the first portion is bonded to one end portion of the second portion. Each of the one or more second interlayer connection conductors includes a third portion including an alloy material including two or more metals or a composite material including one or more metals and a resin. One end portion of the third portion is bonded to the third conductor layer, and an other end portion of the third portion is bonded to the fourth conductor layer. The first conductor layer or the second conductor layer connected to at least one of the first interlayer connection conductors defines the mounting electrode. The radiation electrode includes a conductor layer located closest to the second main surface among the plurality of conductor layers. The third conductor layer or the fourth conductor layer connected to at least one of the second interlayer connection conductors defines the radiation electrode.

According to example embodiments of the present invention, multilayer circuit boards each having excellent connection reliability between interlayer connection conductors and conductor layers, even when the interlayer connection conductors have a small diameter and are arranged at a narrow pitch on a mounting surface for electronic components.

The above and other features, steps, elements, characteristics and advantages of the present invention will become more apparent from the following detailed description of the example embodiments with reference to the attached drawings.

### BRIEF DESCRIPTION OF THE DRAWINGS

FIG. 1 is a cross-sectional view schematically illustrating an example of a multilayer circuit board according to an example embodiment of the present invention.

FIG. 2 is a cross-sectional view schematically illustrating an example of a multilayer circuit board according to a first example embodiment of the present invention.

FIG. 3 is a cross-sectional view schematically illustrating an example of a first interlayer connection conductor 31 according to an example embodiment of the present invention.

FIG. 4 is a cross-sectional view schematically illustrating an example of a second interlayer connection conductor 32 according to an example embodiment of the present invention.

FIG. 5 is a cross-sectional view schematically illustrating an example of a second interlayer connection conductor 33 according to an example embodiment of the present invention.

FIGS. 6A and 6B are cross-sectional views schematically illustrating an example of a method of manufacturing a multilayer circuit board 1A according to an example embodiment of the present invention.

FIG. 7 is a cross-sectional view schematically illustrating an example of a multilayer circuit board according to a second example embodiment of the present invention.

FIG. 8 is a cross-sectional view schematically illustrating an example of a multilayer circuit board according to a third example embodiment of the present invention.

FIG. 9 is a cross-sectional view schematically illustrating an example of a multilayer circuit board according to a fourth example embodiment of the present invention.

FIG. 10 is a cross-sectional view schematically illustrating an example of a first interlayer connection conductor 34 according to an example embodiment of the present invention.

FIG. 11 is a cross-sectional view schematically illustrating an example of a multilayer circuit board according to a fifth example embodiment of the present invention.

FIG. 12 is a cross-sectional view schematically illustrating an example of a multilayer circuit board according to a sixth example embodiment of the present invention.

FIG. 13 is a cross-sectional view schematically illustrating another example of the multilayer circuit board according to the sixth example embodiment of the present invention.

FIG. 14 is a cross-sectional view schematically illustrating an example of a multilayer circuit board according to a seventh example embodiment of the present invention.

FIG. 15 is a cross-sectional view schematically illustrating an example of a multilayer circuit board according to an eighth example embodiment of the present invention.

FIG. 16 is a cross-sectional view schematically illustrating an example of a multilayer circuit board according to a ninth example embodiment of the present invention.

FIG. 17 is a cross-sectional view schematically illustrating an example of a multilayer circuit board according to a tenth example embodiment of the present invention.

### DETAILED DESCRIPTION OF THE EXAMPLE EMBODIMENTS

Hereinafter, multilayer circuit boards according to example embodiments of the present invention will be described in detail with reference to the drawings.

However, the present invention is not limited to the following configurations, and changes can be appropriately applied thereto within a range not changing the scope of the present invention. The present invention also includes combinations of two or more of the example embodiments of the present invention described below.

In the present specification, the term (for example, “vertical”, “parallel”, “orthogonal”, and the like) indicating the relationship between elements and the term indicating the shape of an element are not expressions indicating only a strict meaning, but are expressions that include a substantially equivalent range, for example, a difference of about several %. In addition, in the present specification, “equivalent” is not an expression meaning only a case of being completely equivalent, but is an expression meaning that a case of being substantially equivalent includes, for example, a difference of about several %.

The drawings illustrate schematic views, and dimensions, scales of aspect ratios, and the like may be different from those of actual products. In the drawings, the same or corresponding portions are denoted by the same reference numerals. In each drawing, the same elements are denoted by the same reference numerals, and redundant description will be omitted.

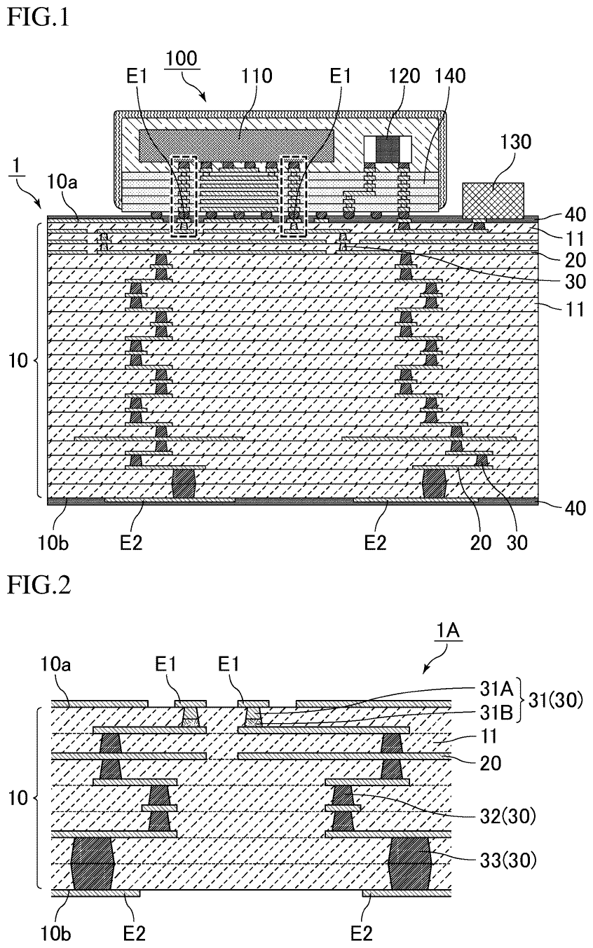

FIG. 1 is a cross-sectional view schematically illustrating an example of a multilayer circuit board according to an example embodiment of the present invention.

A multilayer circuit board 1 illustrated in FIG. 1 includes an insulating base 10, a plurality of conductor layers 20, and a plurality of interlayer connection conductors 30. The multilayer circuit board 1 may be a rigid board or a flexible board. The multilayer circuit board 1 may include a bent portion.

The insulating base 10 is a laminate formed by stacking a plurality of insulating layers 11. The insulating base 10 includes a first main surface 10a (upper surface in FIG. 1) and a second main surface 10b (lower surface in FIG. 1) facing each other in the stacking direction (vertical direction in FIG. 1).

The conductor layer 20 is provided between the insulating layers 11, or on the first main surface 10a, or on the second main surface 10b.

On the first main surface 10a of the insulating base 10, a mounting electrode E1 is provided as the conductor layer 20.

On the second main surface 10b of the insulating base 10, a radiation electrode E2 is provided as the conductor layer 20. The radiation electrode E2 only needs to be a conductor layer located closest to the second main surface 10b among the conductor layers 20, and does not necessarily need to be disposed on the second main surface 10b. The radiation electrode E2 defines a radiation element of an antenna. The operating frequency band of the radiation element is, for example, a high frequency band such as a millimeter wave band.

The radiation electrode E2 is, for example, a planar conductor. In one example embodiment, the radiation electrode E2 is connected to a feed line including the interlayer connection conductor 30 or the like, and defines and functions as a patch antenna.

The interlayer connection conductor 30 penetrates the insulating layer 11 in the stacking direction. Each interlayer connection conductor 30 may penetrate one insulating layer 11 in the stacking direction, or may penetrate two or more insulating layers 11 in the stacking direction.

Each interlayer connection conductor 30 is sandwiched between the conductor layer 20 on the first main surface 10a side and the conductor layer 20 on the second main surface 10b side in the stacking direction.

An insulating protective layer 40 may be provided on the surface layer of the multilayer circuit board 1. The protective layer 40 is, for example, a coverlay, a resist layer, or the like. The protective layer 40 may be provided on both of the first main surface 10a and the second main surface 10b, or may be provided on one of the main surfaces.

An electronic component 100 is mounted on the multilayer circuit board 1 illustrated in FIG. 1. In the example illustrated in FIG. 1, as the electronic component 100, for example, an integrated circuit (IC) 110, a high-frequency component 120, and a connector 130 are mounted on the first main surface 10a of the multilayer circuit board 1. Among them, the integrated circuit 110 and the high-frequency component 120 are mounted on a dielectric substrate 140, and are mounted on the multilayer circuit board 1 via the dielectric substrate 140.

As indicated by a portion surrounded by a broken line in FIG. 1, it is preferable to shorten the path of the current by directly extending the interlayer connection conductor from the electronic component 100 such as the integrated circuit 110 to the multilayer circuit board 1. As a result, the insertion loss can be reduced. Therefore, the interlayer connection conductor 30 connected to the mounting electrode E1 needs to have a smaller diameter and a narrower pitch.

On the other hand, the interlayer connection conductor 30 connected to the radiation electrode E2 does not need to be smaller in diameter and narrower in pitch than the interlayer connection conductor 30 connected to the mounting electrode E1. For example, the connection strength can be increased by making the diameter of the interlayer connection conductor 30 connected to the radiation electrode E2 greater than the diameter of the interlayer connection conductor 30 connected to the mounting electrode E1.

In the multilayer circuit board 1, a first interlayer connection conductor or a second interlayer connection conductor described in each example embodiment described below is provided as the interlayer connection conductor 30.

As described below, the conductor layer 20 connected to at least one first interlayer connection conductor is the mounting electrode E1. In addition, the conductor layer 20 connected to at least one second interlayer connection conductor is the radiation electrode E2.

Each example embodiment illustrated below is an example, and replacement or combination of configurations illustrated in different example embodiments is possible. In the second and subsequent example embodiments, descriptions of matters common to the first example embodiment will be omitted, and only differences will be described. In particular, the same operations and advantageous effects by the same configuration will not be sequentially mentioned for each example embodiment.

### First Example Embodiment

FIG. 2 is a cross-sectional view schematically illustrating an example of a multilayer circuit board according to a first example embodiment of the present invention.

A multilayer circuit board 1A illustrated in FIG. 2 includes an insulating base 10, a plurality of conductor layers 20, and a plurality of interlayer connection conductors 30.

The insulating base 10 is a laminate formed by stacking a plurality of insulating layers 11. The insulating base 10 includes a first main surface 10a (upper surface in FIG. 2) and a second main surface 10b (lower surface in FIG. 2) facing each other in the stacking direction (vertical direction in FIG. 2).

The insulating layer 11 is, for example, a resin insulating layer including a resin as a main component.

When the insulating layer 11 is a resin insulating layer, for example, the insulating layer 11 may be a layer including a thermosetting resin as a main component or a layer including a thermoplastic resin as a main component, but preferably includes a layer including a thermoplastic resin as a main component. In a case where the insulating layer 11 includes a thermoplastic resin, a plurality of resin sheets on which the conductor layer 20 is formed can be stacked, and collectively press-bonded (collectively pressed) by heat treatment.

Examples of the thermosetting resin include an epoxy resin, a phenol resin, a polyimide resin or a modified resin thereof, or an acrylic resin.

Examples of the thermoplastic resin include a liquid crystal polymer (LCP), a fluororesin, a thermoplastic polyimide resin, a polyether ether ketone resin (PEEK), or a polyphenylene sulfide resin (PPS).

The insulating layer 11 preferably includes, for example, a layer including a liquid crystal polymer as a main component. Liquid crystal polymers have lower water absorption than other thermoplastic resins. Therefore, when the insulating layer 11 includes a layer including a liquid crystal polymer as a main component, moisture remaining in the insulating layer 11 can be reduced.

The insulating layer 11 may include an inorganic material such as a ceramic filler, for example.

Examples of the ceramic filler include boron nitride, talc, or fused silica.

The thickness (length in the stacking direction) of one layer of the insulating layer 11 is, for example, preferably about 10 μm or more and about 100 μm or less. The thickness of one layer of the insulating layer 11 may be the same as or different from each other.

The conductor layer 20 is provided between the insulating layers 11, or on the first main surface 10a, or on the second main surface 10b.

The conductor layer 20 may have a patterned shape obtained by patterning the layer into lines or other similar shapes, or may have a planar shape spread over one surface. The shapes of the conductor layers 20 may be the same as or different from each other.

Each of the conductor layers 20 preferably includes Cu (copper) foil, for example.

The conductor layer 20 may include a matte surface on one main surface and a shiny surface on the other main surface. The thickness (length in the stacking direction) of the conductor layer 20 is, for example, preferably about 1 μm or more and about 35 μm or less, and more preferably about 6 μm or more and about 18 μm or less. The thicknesses of the conductor layers 20 may be the same as or different from each other.

The conductor layers 20 may or may not be parallel to each other.

On the first main surface 10a of the insulating base 10, a mounting electrode E1 is provided as the conductor layer 20.

On the second main surface 10b of the insulating base 10, a radiation electrode E2 is provided as the conductor layer 20. The radiation electrode E2 only needs to be a conductor layer located closest to the second main surface 10b among the conductor layers 20, and does not necessarily need to be disposed on the second main surface 10b.

In the multilayer circuit board 1A illustrated in FIG. 2, the interlayer connection conductors 30 include first interlayer connection conductors 31 and second interlayer connection conductors 32 and 33. The interlayer connection conductors 30 may include either the second interlayer connection conductors 32 or 33 alone as the second interlayer connection conductors.

In a cross section perpendicular to the stacking direction, the shape of each interlayer connection conductor 30 is preferably circular. In this case, not only a perfect circle but also an ellipse, an oval, or the like are included in the circle.

Each first interlayer connection conductor 31 includes a first portion 31A and a second portion 31B in the stacking direction.

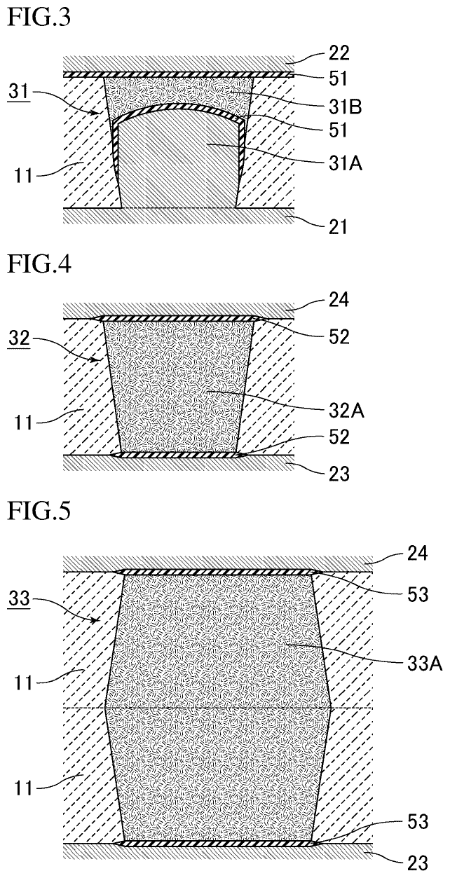

FIG. 3 is a cross-sectional view schematically illustrating an example of the first interlayer connection conductor 31 according to an example embodiment of the present invention. In FIG. 3, the upper and lower sides are interchanged with those in FIG. 2.

The first interlayer connection conductor 31 is sandwiched between a first conductor layer 21 and a second conductor layer 22 in the stacking direction. In the example illustrated in FIG. 3, the first interlayer connection conductor 31 penetrates one insulating layer 11 in the stacking direction.

In the first interlayer connection conductor 31, for example, the first portion 31A includes a single metal including Cu as a main component.

The first portion 31A is, for example, a plated via. Here, the plated via means a film grown by a liquid phase method or a gas phase method.

The second portion 31B includes an alloy material including two or more metals or a composite material including one or more metals and a resin. For example, the second portion 31B includes an alloy including two or more metals selected from Ag, Cu, Ni, Sn, Cr, Pt, Mo, Ga, Ge, Sb, In, Pb, or the like, or a composite material including one or more metals selected from Ag, Cu, Ni, Sn, Cr, Pt, Mo, Ga, Ge, Sb, In, Pb, or the like, and a resin. Specific examples of the alloy material include Cu—Sn alloys such as Cu₅Sn or Cu₅Sn or Ag—Sn alloys such as Ag₃Sn or Ag₅Sn.

The second portion 31B is, for example, a paste via. Here, the paste via means a solidified paste. When the multilayer circuit board 1A is manufactured by collective pressing described below, the second portion 31B defines and functions as a bonding material, so that the first portion 31A and the second conductor layer 22 can be conductively connected.

One end portion of the first portion 31A is bonded to the first conductor layer 21, and the other end portion of the first portion 31A is bonded to one end portion of the second portion 31B.

The first portion 31A and the first conductor layer 21 are directly bonded without interposing a dissimilar material therebetween. Therefore, at the interface between the first portion 31A and the first conductor layer 21, there is a portion where different materials do not exist, that is, a portion where the first portion 31A and the first conductor layer 21 are in direct contact with each other.

When the second portion 31B includes an alloy material, for example, in the second portion 31B, an intermediate layer 51 including at least one of the metals in the second portion 31B and Cu is provided at an end portion on the first portion 31A side. For example, an intermediate layer 51 including Cu and Sn is provided at an end portion on the first portion 31A side. In this case, for example, the intermediate layer 51 is made of a Cu—Sn alloy such as Cu₃Sn or Cu₅Sn. However, the composition of the intermediate layer 51 is different from the composition of the second portion 31B.

The other end portion of the second portion 31B is bonded to the second conductor layer 22.

When the second portion 31B includes an alloy material, for example, in the second portion 31B, an intermediate layer 51 including at least one of the metals in the second portion 31B and Cu is provided at an end portion on the second conductor layer 22 side. For example, in the second portion 31B, the intermediate layer 51 including Cu and Sn is provided at an end portion on the second conductor layer 22 side. In this case, for example, the intermediate layer 51 includes a Cu—Sn alloy such as Cu₅Sn or Cu₅Sn.

The intermediate layer 51 can be confirmed, for example, by observing a cross section of the insulating layer 11 cut in a direction parallel to the stacking direction using a scanning electron microscope (SEM). Since the intermediate layer 51 is different in composition from both of the first portion 31A and the second portion 31B, it is displayed in a color tone different from those of the first portion 31A and the second portion 31B in the SEM photograph.

Even when the kinds of included metal elements are the same, the case where the content ratios of the respective metal elements are different is also considered as being “different in composition”. For example, it can be said that the compositions of Cu₅Sn, Cu₃Sn, Cu₆Sn₅, or the like are all compositions including Cu and Sn as metal species, but the compositions are different from each other because the content ratios of the metal species are different.

FIG. 4 is a cross-sectional view schematically illustrating an example of the second interlayer connection conductor 32 according to an example embodiment of the present invention. In FIG. 4, the upper and lower sides are interchanged with those in FIG. 2.

The second interlayer connection conductor 32 is sandwiched between a third conductor layer 23 and a fourth conductor layer 24 in the stacking direction. In the example illustrated in FIG. 4, the second interlayer connection conductor 32 is provided to penetrate one insulating layer 11 in the stacking direction.

The second interlayer connection conductor 32 includes a third portion 32A.

In the second interlayer connection conductor 32, the third portion 32A includes an alloy material including two or more metals or a composite material including one or more metals and a resin. For example, the third portion 32A includes an alloy including two or more metals selected from Ag, Cu, Ni, Sn, Cr, Pt, Mo, Ga, Ge, Sb, In, Pb, or the like, or a composite material including one or more metals selected from Ag, Cu, Ni, Sn, Cr, Pt, Mo, Ga, Ge, Sb, In, Pb, or the like, and a resin. Specific examples of the alloy material include Cu—Sn alloys such as Cu₅Sn or Cu₅Sn, and Ag—Sn alloys such as Ag₃Sn or Ag₅Sn.

The third portion 32A is, for example, a paste via.

One end portion of the third portion 32A is bonded to the third conductor layer 23, and the other end portion of the third portion 32A is bonded to the fourth conductor layer 24.

When the third portion 32A includes an alloy material, in the third portion 32A, an intermediate layer 52 including at least one of the metals in the third portion 32A and Cu is provided at an end portion on the third conductor layer 23 side and an end portion on the fourth conductor layer 24 side. For example, in the third portion 32A, an intermediate layer 52 including Cu and Sn is provided at an end portion on the third conductor layer 23 side and an end portion on the fourth conductor layer 24 side. In this case, for example, the intermediate layer 52 includes a Cu—Sn alloy such as Cu₃Sn or Cu₅Sn. However, the composition of the intermediate layer 52 is different from the composition of the third portion 32A.

FIG. 5 is a cross-sectional view schematically illustrating an example of the second interlayer connection conductor 33 according to an example embodiment of the present invention. In FIG. 5, the upper and lower sides are interchanged with those in FIG. 2.

The second interlayer connection conductor 33 is sandwiched between the third conductor layer 23 and the fourth conductor layer 24 in the stacking direction. In the example illustrated in FIG. 5, the second interlayer connection conductor 33 penetrates two insulating layers 11 in the stacking direction. The second interlayer connection conductor 33 has a shape in which one set of second interlayer connection conductors 32 is connected in an inverted state.

The second interlayer connection conductor 33 includes a third portion 33A.

In the second interlayer connection conductor 33, the third portion 33A includes an alloy material including two or more metals or a composite material including one or more metals and a resin. For example, the third portion 33A includes an alloy including two or more metals selected from Ag, Cu, Ni, Sn, Cr, Pt, Mo, Ga, Ge, Sb, In, Pb, or the like, or a composite material including one or more metals selected from Ag, Cu, Ni, Sn, Cr, Pt, Mo, Ga, Ge, Sb, In, Pb, or the like, and a resin. Specific examples of the alloy material include Cu—Sn alloys such as Cu₃Sn or Cu₅Sn and Ag—Sn alloys such as Ag₃Sn or Ag₅Sn.

The third portion 33A is, for example, a paste via.

One end portion of the third portion 33A is bonded to the third conductor layer 23, and the other end portion of the third portion 33A is bonded to the fourth conductor layer 24.

When the third portion 33A includes an alloy material, in the third portion 33A, an intermediate layer 53 including at least one of the metals in the third portion 33A and Cu is provided at an end portion on the third conductor layer 23 side and an end portion on the fourth conductor layer 24 side. For example, in the third portion 33A, an intermediate layer 53 including Cu and Sn is provided at an end portion on the third conductor layer 23 side and an end portion on the fourth conductor layer 24 side. For example, the intermediate layer 53 includes a Cu—Sn alloy such as Cu₃Sn or Cu₅Sn. However, the composition of the intermediate layer 53 is different from the composition of the third portion 33A.

In the multilayer circuit board 1A, the first conductor layer 21 or the second conductor layer 22 connected to the at least one first interlayer connection conductor 31 is the mounting electrode E1.

As described above, the interlayer connection conductor 30 connected to the mounting electrode E1 needs to have a smaller diameter and a narrower pitch. In the case of forming an interlayer connection conductor by pouring a conductive paste into a hole provided in a dielectric layer and solidifying the paste as described in WO 2021/060168 A, as the diameter of the hole decreases, the conductive paste is less likely to fill the hole in the depth direction, so that there is a possibility that connection reliability with the conductor foil cannot be sufficiently obtained. Therefore, it is preferable to join the mounting electrode E1 to the first interlayer connection conductor 31 including the first portion 31A such as a plated via, for example, that can be reliably filled even if the diameter of the hole is small and including the second portion 31B such as a paste via, for example, for complementing the connection with the adjacent layer.

The first conductor layer 21 connected to the first interlayer connection conductor 31 may be the mounting electrode E1, and the second conductor layer 22 connected to the first interlayer connection conductor 31 may be the mounting electrode E1. However, as illustrated in FIG. 2, the first conductor layer 21 connected to the first interlayer connection conductor 31 is preferably the mounting electrode E1. That is, as illustrated in FIG. 2, one end portion of the first portion 31A is preferably joined to the mounting electrode E1.

Additionally, in the multilayer circuit board 1A, the third conductor layer 23 or the fourth conductor layer 24 connected to the at least one second interlayer connection conductor 32 or 33 is the radiation electrode E2.

As described above, the interlayer connection conductor 30 connected to the radiation electrode E2 does not need to be smaller in diameter and narrower in pitch than the interlayer connection conductor 30 connected to the mounting electrode E1. Therefore, the interlayer connection conductor 30 bonded to the radiation electrode E2 may be the second interlayer connection conductor 32 or 33 such as a paste via, for example. Unlike the first interlayer connection conductor 31, an additional process such as a plating process, for example, is not required, so that manufacturing efficiency is improved.

In the example illustrated in FIG. 2, the second interlayer connection conductor 33 is connected to the radiation electrode E2, but the second interlayer connection conductor 32 may be connected to the radiation electrode E2. In addition, the radiation electrode E2 connected to the second interlayer connection conductor 32 and the radiation electrode E2 connected to the second interlayer connection conductor 33 may be provided in a mixed manner.

Each insulating layer 11 including any of the first interlayer connection conductors 31 and each insulating layer 11 including any of the second interlayer connection conductors 32 or 33 is preferably a resin insulating layer including a resin as a main component. In this case, the insulating layer 11 including any of the first interlayer connection conductors 31 and the insulating layer 11 including any of the second interlayer connection conductors 32 or 33 may be resin insulating layers that include, as a main component, the same resin as each other or different resins from each other.

The shape, arrangement, and the like of the first interlayer connection conductor 31 are not limited to those shown in FIG. 2 or FIG. 3.

The interlayer connection conductors 30 may include a first interlayer connection conductor 31 sandwiched between the first conductor layer 21 and the second conductor layer 22 that are not the mounting electrodes E1. In this case, the first interlayer connection conductor 31 may be provided on the insulating layer 11 located on the outermost layer on the first main surface 10a side, may be provided on the insulating layer 11 located on the inner layer, or may be provided on the insulating layer 11 located on the outermost layer on the second main surface 10b side. In the same insulating layer 11, the first interlayer connection conductor 31 and the second interlayer connection conductor 32 or 33 may be provided in a mixed manner.

The first interlayer connection conductor 31 may have a tapered shape in which the area of the end portion on the first conductor layer 21 side is smaller than the area of the end portion on the second conductor layer 22 side (see FIG. 3), or may not have a tapered shape. When the first interlayer connection conductor 31 has a tapered shape, the inclination angle may be constant (see FIG. 3) or may not be constant.

An end surface of the first portion 31A on the second conductor layer 22 side may be flat (see FIG. 2), may protrude toward the second portion 31B (see FIG. 3), or may be recessed toward the first portion 31A (not illustrated).

The intermediate layer 51, when provided at the end portion of the second portion 31B on the first portion 31A side, may extend to the interface between the first portion 31A and the insulating layer 11 (see FIG. 3), or may not extend thereto. When the intermediate layer 51 provided at the end portion of the second portion 31B on the first portion 31A side extends to the interface between the first portion 31A and the insulating layer 11, the intermediate layer 51 may not extend to the interface between the first conductor layer 21 and the insulating layer 11 (see FIG. 3), and may extend to the interface.

The intermediate layer 51, when provided at the end portion of the second portion 31B on the second conductor layer 22 side, may extend to the interface between the second conductor layer 22 and the insulating layer 11 (see FIG. 3), or may not extend thereto.

The shape, arrangement, and the like of the second interlayer connection conductor 32 are not limited to those shown in FIG. 2 or FIG. 4.

The interlayer connection conductors 30 may include a second interlayer connection conductor 32 sandwiched between the third conductor layer 23 and the fourth conductor layer 24 that are not the radiation electrodes E2. In this case, the second interlayer connection conductor 32 may be provided on the insulating layer 11 located on the outermost layer on the first main surface 10a side, may be provided on the insulating layer 11 located on the inner layer, or may be provided on the insulating layer 11 located on the outermost layer on the second main surface 10b side. In the same insulating layer 11, the second interlayer connection conductor 32 and the second interlayer connection conductor 33 may be provided in a mixed manner.

The second interlayer connection conductor 32 may have a tapered shape in which the end portion of the end surface on the third conductor layer 23 side is smaller than the area of the end portion on the fourth conductor layer 24 side (see FIG. 4), or may not have a tapered shape. When the second interlayer connection conductor 32 has a tapered shape, the inclination angle may be constant (see FIG. 4) or may not be constant.

The intermediate layer 52, when provided at the end portion of the third portion 32A on the third conductor layer 23 side, may extend to the interface between the third conductor layer 23 and the insulating layer 11 (see FIG. 4), or may not extend thereto. Similarly, the intermediate layer 52, when provided at the end portion of the third portion 32A on the fourth conductor layer 24 side, may extend to the interface between the fourth conductor layer 24 and the insulating layer 11 (see FIG. 4), or may not extend thereto.

The height of the second interlayer connection conductor 32 is preferably greater than the height of the first interlayer connection conductor 31.

The diameter of the second interlayer connection conductor 32 is preferably equal to or greater than the diameter of the first interlayer connection conductor 31. That is, the diameter of the second interlayer connection conductor 32 is preferably equal to the diameter of the first interlayer connection conductor 31 or greater than the diameter of the first interlayer connection conductor 31. When the first interlayer connection conductor 31 has a tapered shape, the diameter of the largest portion is defined as the diameter of the first interlayer connection conductor 31. The same applies to the second interlayer connection conductor 32 and the second interlayer connection conductor 33.

The shape, arrangement, and the like of the second interlayer connection conductor 33 are not limited to those shown in FIG. 2 or FIG. 5.

The interlayer connection conductors 30 may include a second interlayer connection conductor 33 sandwiched between the third conductor layer 23 and the fourth conductor layer 24 that are not the radiation electrodes E2. In this case, the second interlayer connection conductor 33 may be provided on the insulating layer 11 located on the outermost layer on the first main surface 10a side, may be provided on the insulating layer 11 located on the inner layer, or may be provided on the insulating layer 11 located on the outermost layer on the second main surface 10b side. In the same insulating layer 11, the second interlayer connection conductor 32 and the second interlayer connection conductor 33 may be provided in a mixed manner.

The second interlayer connection conductor 33 may have a shape in which one set of second interlayer connection conductors 32 having a tapered shape is connected in an inverted state (see FIG. 5), or may not have a tapered shape.

The intermediate layer 53, when provided at the end portion of the third portion 33A on the third conductor layer 23 side, may extend to the interface between the third conductor layer 23 and the insulating layer 11 (see FIG. 5), or may not extend thereto. Similarly, the intermediate layer 53, when formed at the end portion of the third portion 33A on the fourth conductor layer 24 side, may extend to the interface between the fourth conductor layer 24 and the insulating layer 11 (see FIG. 5), or may not extend thereto.

The height of the second interlayer connection conductor 33 is preferably greater than the height of the first interlayer connection conductor 31. In addition, the height of the second interlayer connection conductor 33 is preferably greater than the height of the second interlayer connection conductor 32.

The diameter of the second interlayer connection conductor 33 is preferably equal to or greater than the diameter of the first interlayer connection conductor 31. That is, the diameter of the second interlayer connection conductor 33 is preferably equal to the diameter of the first interlayer connection conductor 31 or greater than the diameter of the first interlayer connection conductor 31. In addition, the diameter of the second interlayer connection conductor 33 is preferably equal to or greater than the diameter of the second interlayer connection conductor 32. That is, the diameter of the second interlayer connection conductor 33 is preferably equal to the diameter of the second interlayer connection conductor 32 or greater than the diameter of the second interlayer connection conductor 32.

The multilayer circuit board 1A is manufactured, for example, by the following method.

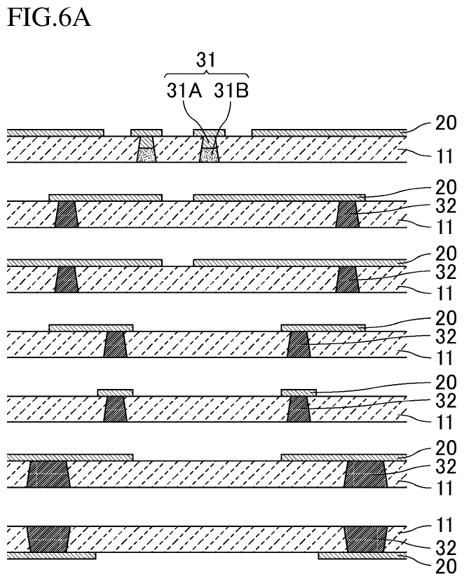

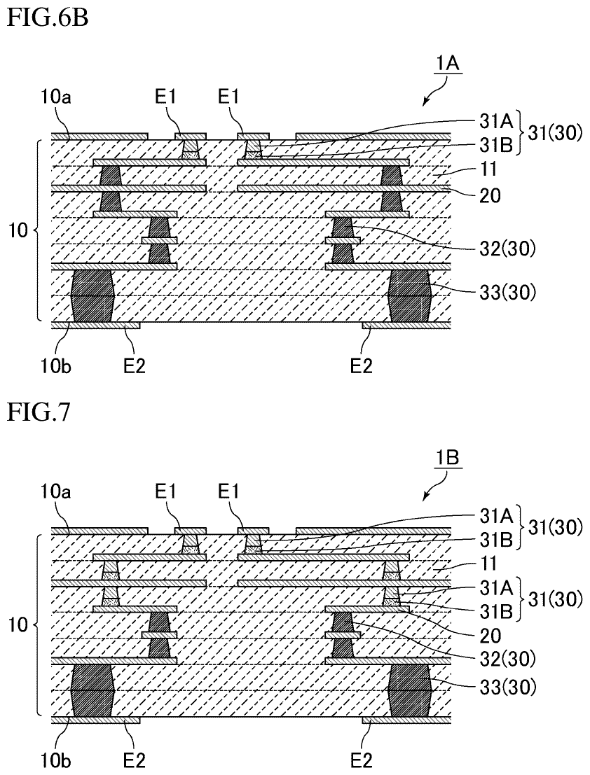

FIGS. 6A and 6B are cross-sectional views schematically illustrating an example of a method of manufacturing the multilayer circuit board 1A according to an example embodiment of the present invention. The multilayer circuit board 1A may be manufactured in a state of one chip (individual piece), or may be manufactured by manufacturing a collective board and then separating the collective board into individual pieces. The collective board here refers to a board including a plurality of multilayer circuit boards 1A.

First, as illustrated in FIG. 6A, a plurality of insulating layers 11 are prepared, and conductor layers 20 are formed on the insulating layers 11, respectively.

For example, a Cu foil is laminated on one main surface of each insulating layer 11, and the Cu foil is patterned by photolithography to form the conductor layer 20. The insulating layer 11 is, for example, a resin sheet including a thermoplastic resin such as a liquid crystal polymer as a main component.

In addition, the first interlayer connection conductor 31 and the second interlayer connection conductor 32 are formed in the insulating layer 11.

For example, a through-hole (also referred to as a via hole) is formed in an insulating layer 11 by a laser or the like such that one surface of the conductor layer 20 is exposed. The through-hole may have a tapered shape in which a hole diameter decreases toward the conductor layer 20. Thereafter, the through-hole is partially filled with Cu as a metal material by a plating treatment to form the first portion 31A. Subsequently, for example, the second portion 31B is formed by filling the inside of the through-hole with a conductive paste including a metal material such as Cu or Sn and a resin material. The conductive paste is solidified by a heating press described below to form the first interlayer connection conductor 31. Separately, a through-hole is formed in an insulating layer 11 with a laser or the like so that one surface of the conductor layer 20 is exposed, and then a conductive paste including, for example, a metal material such as Cu or Sn and a resin material is poured into the through-hole to form the third portion 32A. The conductive paste is solidified by a heating press described below to form the second interlayer connection conductor 32. A second interlayer connection conductor 33 (see FIG. 6B) is formed at a portion where the two third portions 32A are connected in an inverted state.

The respective insulating layers 11 are sequentially stacked, and then heat-pressed (collectively pressed) in the stacking direction. As a result, the multilayer circuit board 1A illustrated in FIG. 6B is manufactured.

According to this example of a manufacturing method, the insulating base 10 can be easily manufactured by collectively pressing the insulating layers 11. Therefore, the manufacturing process of the multilayer circuit board 1A is reduced, and the manufacturing cost can be maintained low.

Although not illustrated in FIG. 2 and the like, a rustproof layer may be provided on the surface of the conductor layer 20. The same applies to the following example embodiments of the present invention.

The rustproof layer is formed by, for example, subjecting the surface of the metal foil to a rustproof treatment using a metal such as Zn, Ni, Cr, Mo, or Pt.

When the multilayer circuit board 1A is produced by the above-described collective pressing, the rustproof layer is disposed at the interface between the conductor layer 20 and the insulating layer 11 to prevent oxidation of the metal foil such as the Cu foil constituting the conductor layer 20, so that it is possible to reduce or prevent a decrease in adhesion between the conductor layer 20 and the insulating layer 11.

### Second Example Embodiment

In a second example embodiment of the present invention, a first interlayer connection conductor is provided in an insulating layer located in the inner layer.

FIG. 7 is a cross-sectional view schematically illustrating an example of a multilayer circuit board according to the second example embodiment of the present invention.

In a multilayer circuit board 1B illustrated in FIG. 7, a first interlayer connection conductor 31 is provided not only in an insulating layer 11 located in the outermost layer on a first main surface 10a side but also in an insulating layer 11 located in the inner layer. In the same insulating layer 11, the first interlayer connection conductor 31 and a second interlayer connection conductor 32 or 33 may be provided in a mixed manner.

As described above, the first interlayer connection conductors may be provided in two of the insulating layers adjacent to each other in the stacking direction. As a result, since the line can be routed to the inner layer via the small-diameter interlayer connection conductor, for example, the parasitic capacitance of the high frequency circuit connecting the integrated circuit to the antenna is reduced, and the characteristics can be improved. In addition, by providing the interlayer connection conductors with a small diameter and a narrow pitch in the ground conductor around the signal line, electric field leakage can be prevented even at a high frequency of several tens of GHz, for example.

### Third Example Embodiment

In a third example embodiment of the present invention, when viewed from the stacking direction, a first interlayer connection conductor overlaps at least a portion of a first or second interlayer connection conductor adjacent in the stacking direction.

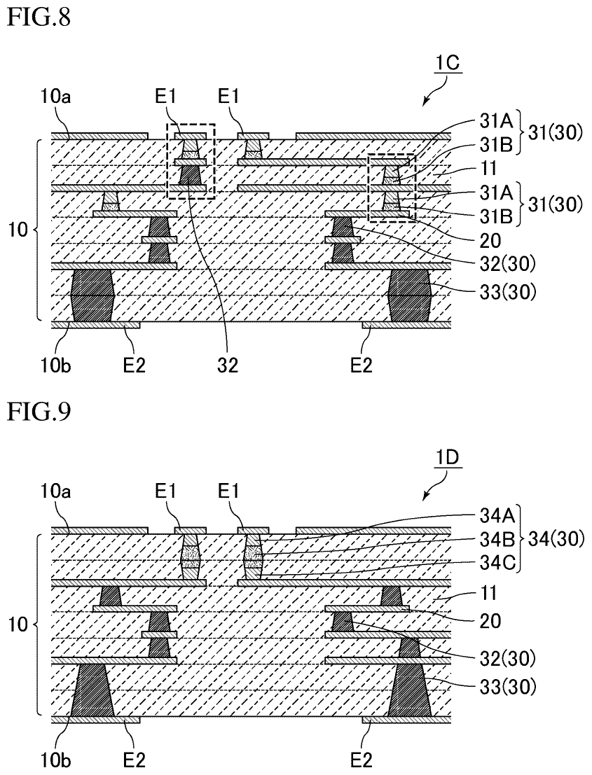

FIG. 8 is a cross-sectional view schematically illustrating an example of a multilayer circuit board according to the third example embodiment of the present invention.

In a multilayer circuit board 1C illustrated in FIG. 8, when viewed from the stacking direction, a first interlayer connection conductor 31 provided in a first insulating layer 11 from the top overlaps at least a portion of a second interlayer connection conductor 32 provided in a second insulating layer 11. In the example illustrated in FIG. 8, the central axis of the first interlayer connection conductor 31 provided in the first insulating layer 11 coincides with the central axis of the second interlayer connection conductor 32 provided in the second insulating layer 11. However, they do not need to coincide.

Further, when viewed from the stacking direction, the first interlayer connection conductor 31 provided in the second insulating layer 11 from the top overlaps at least a portion of the first interlayer connection conductor 31 provided in the third insulating layer 11. In the example illustrated in FIG. 8, the central axis of the first interlayer connection conductor 31 provided in the second insulating layer 11 coincides with the central axis of the first interlayer connection conductor 31 provided in the third insulating layer 11. However, they do not need to coincide.

When the interlayer connection conductors of the upper and lower layers overlap each other in the stacking direction, the degree of freedom in routing the line is increased, so that a large space for the circuit can be ensured. As a result, the inner layer can be densely wired.

In 8, two FIG. interlayer connection conductors including the first interlayer connection conductor overlap each other. However, three or more interlayer connection conductors including the first interlayer connection conductor may overlap each other. For example, the first interlayer connection conductor, the second interlayer connection conductor, and the first interlayer connection conductor may overlap in this order.

In addition, when viewed from the stacking direction, the second interlayer connection conductor may overlap at least a portion of the first or second interlayer connection conductor adjacent in the stacking direction. In this case, two interlayer connection conductors including the second interlayer connection conductor may overlap each other, and three or more interlayer connection conductors including the second interlayer connection conductor may overlap each other.

### Fourth Example Embodiment

In a fourth example embodiment of the present invention, a first interlayer connection conductor further includes a fourth portion, and penetrates the two insulating layers in the stacking direction.

FIG. 9 is a cross-sectional view schematically illustrating an example of a multilayer circuit board according to the fourth example embodiment of the present invention.

In a multilayer circuit board 1D illustrated in FIG. 9, interlayer connection conductors 30 include first interlayer connection conductors 34 and second interlayer connection conductors 32 and 33. The interlayer connection conductors 30 may include either the second interlayer connection conductors 32 or 33 alone as the second interlayer connection conductors. The interlayer connection conductors 30 may further include a first interlayer connection conductor 31 (see FIG. 2).

Each first interlayer connection conductor 34 includes a first portion 34A, a second portion 34B, and a fourth portion 34C in the stacking direction.

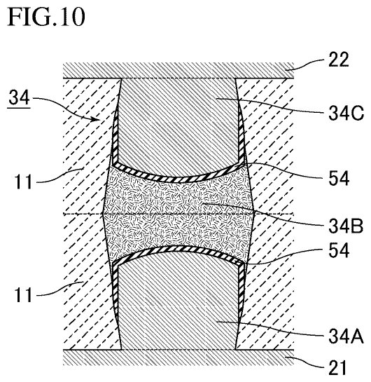

FIG. 10 is a cross-sectional view schematically illustrating an example of the first interlayer connection conductor 34 according to an example embodiment of the present invention. In FIG. 10, the upper and lower sides are interchanged with those in FIG. 9.

The first interlayer connection conductor 34 is sandwiched between a first conductor layer 21 and a second conductor layer 22 in the stacking direction. The first interlayer connection conductor 34 penetrates two insulating layers 11 in the stacking direction. The first interlayer connection conductor 34 has a shape in which one set of first interlayer connection conductors 31 are connected in an inverted state.

In the first interlayer connection conductor 34, the first portion 34A includes a single metal including Cu as a main component, for example.

The first portion 34A is, for example, a plated via.

The second portion n 34B includes an alloy material including two or more metals or a composite material including one or more metals and a resin. For example, the second portion 34B includes an alloy including two or more metals selected from Ag, Cu, Ni, Sn, Cr, Pt, Mo, Ga, Ge, Sb, In, Pb, or the like, or a composite material including one or more metals selected from Ag, Cu, Ni, Sn, Cr, Pt, Mo, Ga, Ge, Sb, In, Pb, or the like, and a resin. Specific examples of the alloy material include Cu—Sn alloys such as Cu₃Sn or Cu₅Sn and Ag—Sn alloys such as Ag₃Sn or Ag₅Sn.

The second portion 34B is, for example, a paste via.

The fourth portion 34C includes a single metal including Cu as a main component, for example.

The fourth portion 34C is, for example, a plated via.

One end portion of the first portion 34A is bonded to the first conductor layer 21, and the other end portion of the first portion 34A is bonded to one end portion of the second portion 34B.

The first portion 34A and the first conductor layer 21 are directly bonded without interposing a dissimilar material therebetween. Therefore, at the interface between the first portion 34A and the first conductor layer 21, there is a portion where different materials do not exist, that is, a portion where the first portion 34A and the first conductor layer 21 are in direct contact with each other.

When the second portion 34B includes an alloy material, in the second portion 34B, an intermediate layer 54 including at least one of the metals in the second portion 34B and Cu is provided at an end portion on the first portion 34A side. For example, in the second portion 34B, an intermediate layer 54 including Cu and Sn is provided at an end portion on the first portion 34A side. In this case, for example, the intermediate layer 54 includes a Cu—Sn alloy such as Cu₃Sn or Cu₅Sn. However, the composition of the intermediate layer 54 is different from the composition of the second portion 34B.

One end portion of the fourth portion 34C is bonded to the other end portion of the second portion 34B, and the other end portion of the fourth portion 34C is bonded to the second conductor layer 22.

The fourth portion 34C and the second conductor layer 22 are directly bonded without interposing a dissimilar material therebetween. Therefore, at the interface between the fourth portion 34C and the second conductor layer 22, there is a portion where different materials do not exist, that is, a portion where the fourth portion 34C and the second conductor layer 22 are in direct contact with each other.

When the second portion 34B includes an alloy material, in the second portion 34B, an intermediate layer 54 including at least one of the metals in the second portion 34B and Cu is provided at an end portion on the fourth portion 34C side. For example, in the second portion 34B, an intermediate layer 54 including Cu and Sn is provided at an end portion on the fourth portion 34C side. In this case, for example, the intermediate layer 54 includes a Cu—Sn alloy such as Cu₃Sn or Cu₅Sn. However, the composition of the intermediate layer 54 is different from the composition of the second portion 34B.

When the first interlayer connection conductor 34 is provided, the degree of freedom in routing the line is increased as compared with the first interlayer connection conductor 31, so that a large circuit space can be ensured. As a result, the inner layer can be densely wired.

The shape, arrangement, and the like of the first interlayer connection conductor 34 are not limited to those shown in FIG. 9 or FIG. 10.

The interlayer connection conductors 30 may include a first interlayer connection conductor 34 sandwiched between the first conductor layer 21 and the second conductor layer 22 that are not the mounting electrodes E1. In this case, the first interlayer connection conductor 34 may be provided on the insulating layer 11 located on the outermost layer on a first main surface 10a side, may be provided on the insulating layer 11 located on the inner layer, or may be provided on the insulating layer 11 located on the outermost layer on a second main surface 10b side. In the multilayer circuit board 1D, the first interlayer connection conductor 31 and the first interlayer connection conductor 34 may be provided in a mixed manner.

The first interlayer connection conductor 34 may have a shape in which one set of first interlayer connection conductors 31 having a tapered shape is connected in an inverted state (see FIG. 10), or may not have a tapered shape.

The height of the first interlayer connection conductor 34 is preferably greater than the height of the first interlayer connection conductor 31. In addition, the height of the first interlayer connection conductor 34 may be equal to the height of the second interlayer connection conductor 32 or 33, may be greater than the height of the second interlayer connection conductor 32 or 33, and may be smaller than the height of the second interlayer connection conductor 32 or 33.

The diameter of the first interlayer connection conductor 34 is preferably equal to the diameter of the first interlayer connection conductor 31. The diameter of the first interlayer connection conductor 34 is preferably equal to or less than the diameter of the second interlayer connection conductors 32 or 33. That is, the diameter of the first interlayer connection conductor 34 is preferably equal to the diameter of the second interlayer connection conductor 32 or 33, or smaller than the diameter of the second interlayer connection conductor 32 or 33.

### Fifth Example Embodiment

In a fifth example embodiment of the present invention, a recess is provided on a second main surface of an insulating base, and the insulating base is bent toward a first main surface side at the recess.

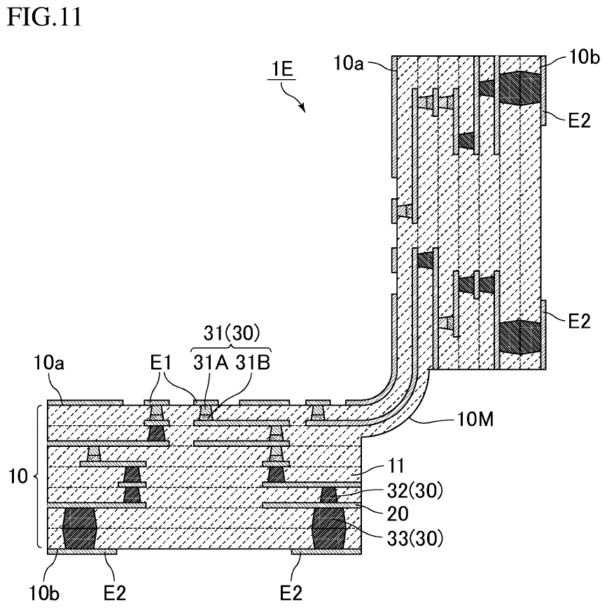

FIG. 11 is a cross-sectional view schematically illustrating an example of a multilayer circuit board according to the fifth example embodiment of the present invention.

In a multilayer circuit board 1E illustrated in FIG. 11, a recess 10M is provided in a second main surface 10b of an insulating base 10, and the insulating base 10 is bent toward the first main surface 10a side at the recess 10M. The depth, bending angle, and the like of the recess 10M are not limited. In addition, a plurality of recesses 10M may be provided.

By forming the recess on the second main surface and thinning the insulating base, the insulating base is easily bent. As a result, for example, since the directions of the antenna surfaces having different frequencies and bands can be changed, one multilayer circuit board can have a plurality of antenna directivities.

### Sixth Example Embodiment

In a sixth example embodiment of the present invention, the material of an insulating layer provided with a second interlayer connection conductor connected to a radiation electrode is different from the material of an insulating layer provided with a first interlayer connection conductor connected to a mounting electrode. For example, the dielectric constant of the insulating layer provided with the second interlayer connection conductor connected to the radiation electrode is higher than the dielectric constant of the insulating layer provided with the first interlayer connection conductor connected to the mounting electrode.

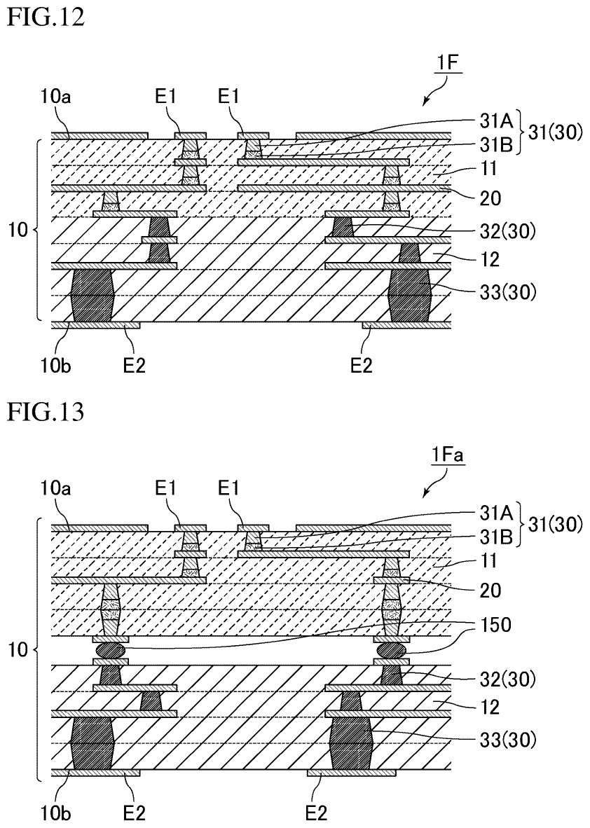

FIG. 12 is a cross-sectional view schematically illustrating an example of a multilayer circuit board according to the sixth example embodiment of the present invention.

In a multilayer circuit board 1F illustrated in FIG. 12, an insulating base 10 includes an insulating layer 11 and an insulating layer 12 including a material different from that of the insulating layer 11. For example, the insulating base 10 includes the insulating layer 11 and the insulating layer 12 having a dielectric constant higher than that of the insulating layer 11.

In the example illustrated in FIG. 12, a first interlayer connection conductor 31 is provided in the insulating layer 11, and a second interlayer connection conductor 32 or 33 is provided in the insulating layer 12, but the boundary between the insulating layer 11 and the insulating layer 12 is not limited, and it is sufficient that the material of the insulating layer 12, in which the second interlayer connection conductor (the second interlayer connection conductor 33 in FIG. 12) connected to a radiation electrode E2 is provided, is different from the material of the insulating layer 11, in which the first interlayer connection conductor 31 connected to a mounting electrode E1 is provided. For example, in the insulating layer 11, the first interlayer connection conductor 31 or 34 may be provided, and the second interlayer connection conductor 32 or 33 may be provided. Similarly, in the insulating layer 12, the first interlayer connection conductor 31 or 34 may be provided, and the second interlayer connection conductor 32 or 33 may be provided.

The insulating layer 11 is, for example, a resin insulating layer including a thermoplastic resin as a main component. Examples of the thermoplastic resin include a liquid crystal polymer, a fluororesin, a thermoplastic polyimide resin, a polyether ether ketone resin, or a polyphenylene sulfide resin.

The insulating layer 12 is, for example, a resin insulating layer including a thermosetting resin as a main component. Examples of the thermosetting resin include an epoxy resin, a phenol resin, a polyimide resin or a modified resin thereof, or an acrylic resin.

The insulating layer 12 may be a resin insulating layer including an inorganic material such as a ceramic filler, for example. In this case, for example, the insulating layer 12 may be a resin insulating layer including a thermoplastic resin as a main component, or may be a resin insulating layer including a thermosetting resin as a main component.

Alternatively, for example, the insulating layer 12 may be a ceramic insulating layer including a ceramic as a main component, such as a low-temperature co-fired ceramic (LTCC) or a high-temperature co-fired ceramic (HTCC). As the insulating layer 12, a resin insulating layer and a ceramic insulating layer may be combined.

For example, by making the dielectric constant of the insulating layer higher on the radiation electrode side than on the mounting electrode side, the degree of freedom increases in the band range of the antenna. On the other hand, since there are many lines such as signal lines whose characteristics are important on the mounting electrode side, the insertion loss is improved by lowering the dielectric constant of the insulating layer. As described above, by stacking a plurality of types of insulating layers on the same multilayer circuit board, the degree of freedom in design is improved.

In the present example embodiment, an insulating layer with a high dielectric constant has a high loss tangent. Thus, in the sixth example embodiment of the present invention, preferably, the dielectric constant of the insulating layer provided with a second interlayer connection conductor connected to a radiation electrode is higher than the dielectric constant of the insulating layer provided with a first interlayer connection conductor connected to a mounting electrode, or the loss tangent of the insulating layer provided with a second interlayer connection conductor connected to a radiation electrode is higher than the loss tangent of the insulating layer provided with a first interlayer connection conductor connected to a mounting electrode, or both of these conditions are satisfied.

In the case described above, the dielectric constant or loss tangent of the insulating layer is lower on the mounting electrode side than on the radiation electrode side. Routing the wiring line from an integrated circuit to an antenna on the mounting surface side enables increasing the conductor width, which can result in reduced insertion loss (I. L.).

Meanwhile, the dielectric constant or loss tangent of the insulating layer is higher on the radiation electrode side than on the mounting electrode side. This facilitates adjustment of the frequency bandwidth of the antenna. Additionally, the antenna can be miniaturized, enabling module miniaturization.

In the multilayer circuit board 1F illustrated in FIG. 12, for example, a first substrate portion including the insulating layer 11 provided with the first interlayer connection conductor 31 connected to the mounting electrode E1 and a second substrate portion including the insulating layer 12 provided with the second interlayer connection conductor (the second interlayer connection conductor 33 in FIG. 12) connected to the radiation electrode E2 may be joined by a method such as bonding, for example.

FIG. 13 is a cross-sectional view schematically illustrating another example of the multilayer circuit board according to the sixth example embodiment of the present invention.

As with a multilayer circuit board 1Fa shown in FIG. 13, the first substrate portion including the insulating layer 11 provided with the first interlayer connection conductor 31 connected to the mounting electrode E1 and the second substrate portion including the insulating layer 12 provided with the second interlayer connection conductor (the second interlayer connection conductor 33 in FIG. 12) connected to the radiation electrode E2 may be bonded to each other with a conductive bonding material 150 such as, for example, solder interposed therebetween. In this case, the electrode of the first substrate portion and the electrode of the second substrate portion are bonded via the conductive bonding material 150. By bonding the second substrate portion provided with the radiation electrode E2 to the first substrate portion, the required band of the antenna can be adjusted, so that the degree of freedom is improved.

### Seventh Example Embodiment

In a seventh example embodiment of the present invention, the inclinations of radiation electrodes are different from each other.

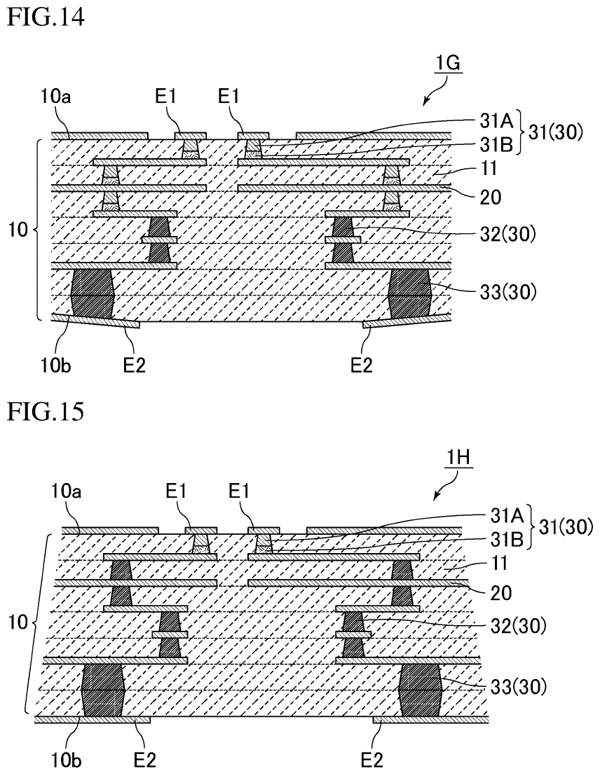

FIG. 14 is a cross-sectional view schematically illustrating an example of a multilayer circuit board according to the seventh example embodiment of the present invention.

In a multilayer circuit board 1G illustrated in FIG. 14, two or more radiation electrodes E2 are provided on a main surface of the insulating layer 11 in the same layer, and the inclinations of radiation electrodes E2 with respect to a first main surface 10a are different from each other.

The multilayer circuit board 1G can be manufactured, for example, by changing the direction of the radiation electrode E2 on a second main surface 10b side at the time of collective pressing.

By tilting the radiation electrodes in a plurality of directions, a structure in which the directivity of the antenna is changed can be obtained.

The number of radiation electrodes E2 may be two or three or more. The radiation electrode E2 is not necessarily provided on the second main surface 10b. As long as the inclination of each radiation electrode E2 with respect to the first main surface 10a is different, a radiation electrode E2 parallel to the first main surface 10a may be included. When three or more radiation electrodes E2 are provided, radiation electrodes E2 having the same inclination may be included.

### Eighth Example Embodiment

In an eighth example embodiment of the present invention, the area of a main surface of an insulating layer on which a radiation electrode is provided is greater than the area of a main surface of an insulating layer on which a mounting electrode is provided.

FIG. 15 is a cross-sectional view schematically illustrating an example of a multilayer circuit board according to the eighth example embodiment of the present invention.

In a multilayer circuit board 1H illustrated in FIG. 15, the area of the main surface (a second main surface 10b in FIG. 15) of an insulating layer 11 provided with a radiation electrode E2 is greater than the area of the main surface (a first main surface 10a in FIG. 15) of the insulating layer 11 provided with a mounting electrode E1. The radiation electrode E2 is not necessarily provided on the second main surface 10b.

By making the area of the main surface on the radiation electrode side greater than the area of the main surface on the mounting electrode side, the radiation electrode can be expanded in a limited substrate size, so that characteristics can be improved.

### Ninth Example Embodiment

In a ninth example embodiment of the present invention, an electronic component is mounted on a first main surface.

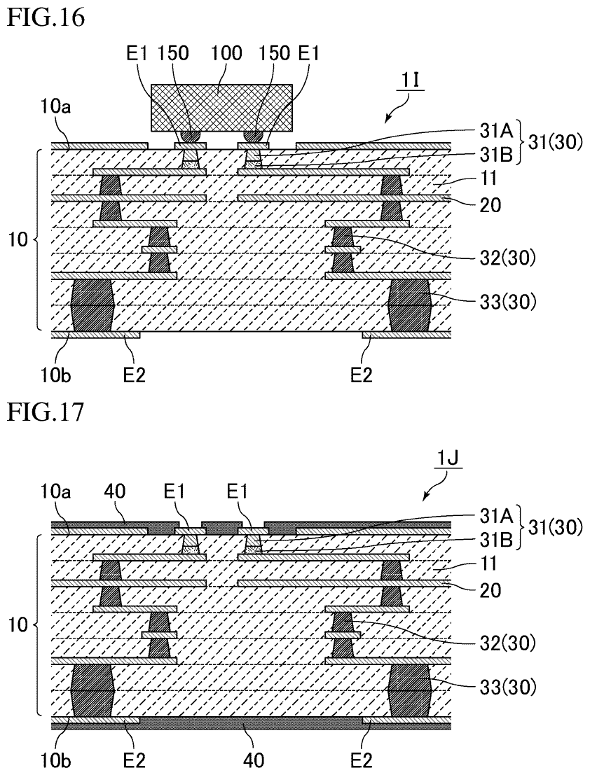

FIG. 16 is a cross-sectional view schematically illustrating an example of a multilayer circuit board according to the ninth example embodiment of the present invention.

In a multilayer circuit board 1I illustrated in FIG. 16, an electronic component 100 is mounted on a first main surface 10a. The electronic component 100 is, for example, an integrated circuit (IC) or a connector. The electronic component 100 is connected to the multilayer circuit board 1I via a conductive bonding material 150 such as solder, for example.

An integrated module substrate can be provided by mounting an electronic component on the first main surface. In particular, by providing a first interlayer connection conductor 31 on a mounting electrode E1 side, an electronic component having a narrow pitch of mounting bumps can be mounted.

### Tenth Example Embodiment

In a tenth example embodiment of the present invention, an insulating protective layer is provided on a first main surface.

FIG. 17 is a cross-sectional view schematically illustrating an example of a multilayer circuit board according to the tenth example embodiment of the present invention.

In a multilayer circuit board 1J illustrated in FIG. 17, an insulating protective layer 40 is provided on a first main surface 10a. At least a portion of a mounting electrode E1 is exposed from the protective layer 40. As illustrated in FIG. 17, the insulating protective layer 40 may be provided on a second main surface 10b. The protective layer 40 is, for example, a coverlay, a resist layer, or the like.

By providing the protective layer on the surface layer of the multilayer circuit board, the adhesion strength between the insulating layer and the conductor layer is improved, and the conductor layer is hardly peeled off from the insulating layer. In particular, when the mounting electrodes are arranged at high density on the first main surface, the protective layer can prevent short circuiting or migration between lands caused by foreign matters or the like.

### Other Example Embodiments

The multilayer circuit board of the present invention is not limited to the above-described example embodiments, and various applications and modifications can be made within the scope of the present invention with respect to the configuration, manufacturing conditions, and the like of the multilayer circuit board.

For example, a first interlayer connection conductor 31 may penetrate through one insulating layer, or may penetrate through two or more insulating layers. When the first interlayer connection conductor 31 penetrates two or more insulating layers, the configurations of the insulating layers may be the same as or different from each other. In addition, when the first interlayer connection conductor 31 penetrates two or more insulating layers, the thicknesses of the insulating layers may be the same as or different from each other.

A second interlayer connection conductor 32 may penetrate through one insulating layer or may penetrate through two or more insulating layers. When the second interlayer connection conductor 32 penetrates two or more insulating layers, the configurations of the insulating layers may be the same as or different from each other. In addition, when the second interlayer connection conductor 32 penetrates two or more insulating layers, the thicknesses of the insulating layers may be the same as or different from each other.

A second interlayer connection conductor 33 may penetrate through two insulating layers, or may penetrate through three or more insulating layers. The configurations of the insulating layers may be the same as or different from each other. The thicknesses of the insulating layers may be the same as or different from each other.

A first interlayer connection conductor 34 may penetrate through two insulating layers or may penetrate through three or more insulating layers. When the first interlayer connection conductor 34 penetrates two or more insulating layers, the configurations of the insulating layers may be the same as or different from each other. In addition, when the first interlayer connection conductor 34 penetrates two or more insulating layers, the thicknesses of the insulating layers may be the same as or different from each other.

The following content is disclosed in the present specification.

<1>

A multilayer circuit board including an insulating base including a stack of a plurality of insulating layers and a first main surface and a second main surface facing each other in a stacking direction, a plurality of conductor layers between the plurality of insulating layers, or on the first main surface, or on the second main surface, a plurality of interlayer connection conductors penetrating at least one of the insulating layers in the stacking direction, a mounting electrode on the first main surface, and a radiation electrode located closer to the second main surface than the mounting electrode is in the stacking direction, wherein the plurality of conductor layers include a first conductor layer, a second conductor layer, a third conductor layer, and a fourth conductor layer, each including Cu foil, the plurality of interlayer connection conductors include one or more first interlayer connection conductors sandwiched between the first conductor layer and the second conductor layer in the stacking direction, and one or more second interlayer connection conductors sandwiched between the third conductor layer and the fourth conductor layer in the stacking direction, each of the one or more first interlayer connection conductors includes a first portion and a second portion in the stacking direction, the first portion including a single metal including Cu as a main component, the second portion including an alloy material including two or more metals or a composite material including one or more metals and a resin, one end portion of the first portion is bonded to the first conductor layer, and an other end portion of the first portion is bonded to one end portion of the second portion, each of the one or more second interlayer connection conductors includes a third portion including an alloy material including two or more metals or a composite material including one or more metals and a resin, one end portion of the third portion is bonded to the third conductor layer, and an other end portion of the third portion is bonded to the fourth conductor layer, the first conductor layer or the second conductor layer connected to at least one of the first interlayer connection conductors defines the mounting electrode, the radiation electrode includes a conductor layer located closest to the second main surface among the plurality of conductor layers, and the third conductor layer or the fourth conductor layer connected to at least one of the second interlayer connection conductors defines the radiation electrode.

<2>

The multilayer circuit board according to <1>, wherein the first conductor layer connected to at least one of the one or more first interlayer connection conductors is included in the mounting electrode.

<3>

The multilayer circuit board according to <1> or <2>, wherein each of the plurality of insulating layers including any of the one or more first interlayer connection conductors and each of the plurality of insulating layers including any of the one or more second interlayer connection conductors includes a resin insulating layer including a resin as a main component.

<4>

The multilayer circuit board according to any one of <1> to <3>, wherein the second portion includes an alloy material including two or more metals, in the second portion, an intermediate layer including at least one of the metals in the second portion and Cu is provided at an end portion on the first portion side, the third portion includes an alloy material including two or more metals, and, in the third portion, an intermediate layer including at least one of the metals in the third portion and Cu is provided at an end portion on the third conductor layer side and an end portion on the fourth conductor layer side.

<5>

The multilayer circuit board according to any one of <1> to <4>, wherein an other end portion of the second portion is bonded to the second conductor layer.

<6>

The multilayer circuit board according to any one of <1> to <4>, wherein the one or more first interlayer connection conductors further include a fourth portion including a single metal including Cu as a main component, and one end of the fourth portion is bonded to the other end portion of the second portion, and an other end portion of the fourth portion is bonded to the second conductor layer.

<7>

The multilayer circuit board according to any one of <1> to <6>, wherein a height of the one or more second interlayer connection conductors is greater than a height of the one or more first interlayer connection conductors.

<8>

The multilayer circuit board according to any one of <1> to <7>, wherein a diameter of the one or more second interlayer connection conductors is equal to or greater than a diameter of the one or more first interlayer connection conductors.

<9>

The multilayer circuit board according to any one of <1> to <8>, wherein the one or more first interlayer connection conductors are provided in two of the plurality of insulating layers adjacent to each other in the stacking direction.

<10>

The multilayer circuit board according to any one of <1> to <9>, wherein at least one of the one or more first interlayer connection conductors and at least one of the one or more second interlayer connection conductors are provided in a same insulating layer of the plurality of insulating layers.

<11>

The multilayer circuit board according to any one of <1> to <10>, wherein at least one of the one or more first interlayer connection conductors overlaps at least a portion of the one or more first or second interlayer connection conductors adjacent in the stacking direction as viewed from the stacking direction.

<12>

The multilayer circuit board according to any one of <1> to <11>, wherein a recess is provided in the second main surface of the insulating base, and the insulating base is bent toward the first main surface side at the recess.

<13>

The multilayer circuit board according to any one of <1> to <12>, wherein a material of the insulating layer provided with the second interlayer connection conductor connected to the radiation electrode is different from a material of the insulating layer provided with the first interlayer connection conductor connected to the mounting electrode.

<14>

The multilayer circuit board according to any one of <1> to <13>, wherein a dielectric constant of the insulating layer provided with the second interlayer connection conductor connected to the radiation electrode is higher than a dielectric constant of the insulating layer provided with the first interlayer connection conductor connected to the mounting electrode.

<15>

The multilayer circuit board according to <13> or <14>, wherein a first substrate portion including the insulating layer provided with the second interlayer connection conductor connected to the radiation electrode is bonded to a second substrate portion including the insulating layer provided with the first interlayer connection conductor connected to the mounting electrode.

<16>

The multilayer circuit board according to any one of <1> to <15>, wherein two or more of the radiation electrodes are provided on a main surface of a same insulating layer of the plurality of insulating layers, and inclinations of the two or more radiation electrodes with respect to the first main surface are different from each other.

<17>

The multilayer circuit board according to any one of <1> to <16>, wherein an area of a main surface of the insulating layer on which the radiation electrode is provided is greater than an area of a main surface of the insulating layer on which the mounting electrode is provided.

<18>

The multilayer circuit board according to any one of <1> to <17>, further including an electronic component mounted on the first main surface.

<19>

The multilayer circuit board according to any one of <1> to <18>, further including an insulating protective layer provided on the first main surface.

<20>

The multilayer circuit board according to any one of <1> to <19>, wherein the plurality of insulating layers include a layer including a thermoplastic resin as a main component.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer circuit board comprising:
an insulating base including a stack of a plurality of insulating layers, and a first main surface and a second main surface facing each other in a stacking direction;
a plurality of conductor layers between the plurality of insulating layers, or on the first main surface, or on the second main surface;
a plurality of interlayer connection conductors penetrating at least one of the insulating layers in the stacking direction;
a mounting electrode on the first main surface; and
a radiation electrode located closer to the second main surface than the mounting electrode is in the stacking direction; wherein
the plurality of conductor layers include a first conductor layer, a second conductor layer, a third conductor layer, and a fourth conductor layer, each including Cu foil;
the plurality of interlayer connection conductors include one or more first interlayer connection conductors sandwiched between the first conductor layer and the second conductor layer in the stacking direction, and one or more second interlayer connection conductors sandwiched between the third conductor layer and the fourth conductor layer in the stacking direction;
each of the one or more first interlayer connection conductors includes a first portion and a second portion in the stacking direction, the first portion including a single metal including Cu as a main component, the second portion including an alloy material including two or more metals or a composite material including one or more metals and a resin;
one end portion of the first portion is bonded to the first conductor layer, and an other end portion of the first portion is bonded to one end portion of the second portion;
each of the one or more second interlayer connection conductors includes a third portion including an alloy material including two or more metals or a composite material including one or more metals and a resin;
one end portion of the third portion is bonded to the third conductor layer, and an other end portion of the third portion is bonded to the fourth conductor layer;
the first conductor layer or the second conductor layer connected to at least one of the first interlayer connection conductors defines the mounting electrode;
the radiation electrode includes a conductor layer located closest to the second main surface among the plurality of conductor layers; and
the third conductor layer or the fourth conductor layer connected to at least one of the one or more second interlayer connection conductors defines the radiation electrode.

2. The multilayer circuit board according to claim 1, wherein the first conductor layer connected to at least one of the one or more first interlayer connection conductors is included in the mounting electrode.

3. The multilayer circuit board according to claim 1, wherein each of the plurality of insulating layers including any of the one or more first interlayer connection conductors and each of the plurality of insulating layers including any of the one or more second interlayer connection conductors includes a resin insulating layer including a resin as a main component.

4. The multilayer circuit board according to claim 1, wherein
the second portion includes an alloy material including two or more metals;
in the second portion, an intermediate layer including at least one of the metals in the second portion and Cu is provided at an end portion on the first portion side;
the third portion includes an alloy material including two or more metals; and
in the third portion, an intermediate layer including at least one of the metals in the third portion and Cu is provided at an end portion on the third conductor layer side and an end portion on the fourth conductor layer side.

5. The multilayer circuit board according to claim 1, wherein an other end portion of the second portion is bonded to the second conductor layer.

6. The multilayer circuit board according to claim 1, wherein
the one or more first interlayer connection conductors further include a fourth portion including a single metal including Cu as a main component; and
one end of the fourth portion is bonded to an other end portion of the second portion, and an other end portion of the fourth portion is bonded to the second conductor layer.

7. The multilayer circuit board according to claim 1, wherein a height of the one or more second interlayer connection conductors is greater than a height of the one or more first interlayer connection conductors.

8. The multilayer circuit board according to claim 1, wherein a diameter of the one or more second interlayer connection conductors is equal to or greater than a diameter of the one or more first interlayer connection conductors.

9. The multilayer circuit board according to claim 1, wherein the one or more first interlayer connection conductors are provided in two of the plurality of insulating layers adjacent to each other in the stacking direction.

10. The multilayer circuit board according to claim 1, wherein at least one of the one or more first interlayer connection conductors and at least one of the one or more second interlayer connection conductors are provided in a same insulating layer of the plurality of insulating layers.

11. The multilayer circuit board according to claim 1, wherein at least one of the one or more first interlayer connection conductors overlaps at least a portion of the one or more first or second interlayer connection conductors adjacent in the stacking direction as viewed from the stacking direction.

12. The multilayer circuit board according to claim 1, wherein
a recess is provided in the second main surface of the insulating base; and
the insulating base is bent toward the first main surface side at the recess.

13. The multilayer circuit board according to claim 1, wherein a material of the insulating layer provided with the second interlayer connection conductor connected to the radiation electrode is different from a material of the insulating layer provided with the first interlayer connection conductor connected to the mounting electrode.

14. The multilayer circuit board according to claim 1, wherein a dielectric constant of the insulating layer provided with the second interlayer connection conductor connected to the radiation electrode is higher than a dielectric constant of the insulating layer provided with the first interlayer connection conductor connected to the mounting electrode.

15. The multilayer circuit board according to claim 13, wherein a first substrate portion including the insulating layer provided with the second interlayer connection conductor connected to the radiation electrode is bonded to a second substrate portion including the insulating layer provided with the first interlayer connection conductor connected to the mounting electrode.

16. The multilayer circuit board according to claim 1, wherein
two or more of the radiation electrodes are provided on a main surface of a same one of the plurality of insulating layers; and
inclinations of the radiation electrodes with respect to the first main surface are different from each other.

17. The multilayer circuit board according to claim 1, wherein an area of a main surface of the insulating layer on which the radiation electrode is provided is greater than an area of a main surface of the insulating layer on which the mounting electrode is provided.

18. The multilayer circuit board according to claim 1, further comprising an electronic component mounted on the first main surface.

19. The multilayer circuit board according to claim 1, further comprising an insulating protective layer provided on the first main surface.

20. The multilayer circuit board according to claim 1, wherein the plurality of insulating layers include a layer including a thermoplastic resin as a main component.
